(19) United States
(12) Patent Application Publication
(10) Pub. No.: US 2023/0176436 A1
(43) Pub. Date: Jun. 8, 2023

(54) LIQUID CRYSTAL WRITING APPARATUS AND METHOD FOR IMPLEMENTING LOCAL ERASURE BY USING LIGHT

(71) Applicant: SHANDONG LANBEISITE EDUCATIONAL EQUIPMENT GROUP, Jinan, Shandong (CN)

(72) Inventors: Qingbo LI, Jinan (CN); Mengxun YANG, Jinan (CN)

(73) Assignee: SHANDONG LANBEISITE EDUCATIONAL EQUIPMENT GROUP, Jinan, Shandong (CN)

(21) Appl. No.: 17/610,504

(22) PCT Filed: Jul. 27, 2021
(86) PCT No.: PCT/CN2021/108705

§ 371 Date: Nov. 11, 2021

(30) Foreign Application Priority Data
Nov. 30, 2020 (CN) 202011371805.9
Jan. 29, 2021 (CN) 202110130397.6

(51) Int. Cl. G02F 1/1368; G02F 1/1333; G02F 1/139; H01L 27/12; G06F 3/042

(52) U.S. Cl. CPC G02F 1/1368; G02F 1/13338; G02F 1/1391; H01L 27/124; G06F 3/042; G02F 2202/16

(57) ABSTRACT

A liquid crystal writing apparatus and corresponding method for implementing local erasure by using light, the apparatus includes: a conductive layer, a bistable liquid crystal layer, and a base layer that are sequentially arranged. The base layer is integrated with: a plurality of erasing units arranged in an array, where an erasing electrode and a thin film transistor (TFT) connected to the erasing electrode are disposed in each erasing unit; at least one first conducting wire configured to supply a control voltage to gate of each TFT; and at least one second conducting wire configured to supply an input voltage to source of each TFT, where the TFT is configured to be in a critical cut off state, and then be turned on by receiving light of a set intensity, to input a set voltage to a corresponding erasing electrode.

### TECHNICAL FIELD

The present invention relates to the field of liquid crystal writing board technologies, and in particular, to a liquid crystal writing apparatus and method for implementing local erasure by using light.

### BACKGROUND

A working principle of current liquid crystal writing boards on the market is that written content on a liquid crystal writing board is displayed and/or erased by using a bistable characteristic of a liquid crystal. A cholesteric liquid crystal is used as an example, a liquid crystal state at a pen head is changed through pressure acting on the liquid crystal writing board and a writing pressure track of a writing pen is recorded, and then corresponding written content is displayed; and a structure of the cholesteric liquid crystal is changed by applying an electric field, so that the writing track on the liquid crystal writing board disappears to implement erasure.

According to a technical solution in which local erasure is implemented by segmenting an upper conductive layer and a lower conductive layer disclosed in the prior art, an erasing member is first positioned by using a positioning circuit to determine an erased region; and then set voltages are respectively applied, by using a row and column driver circuit, to corresponding conductive regions on the two conductive layers covering the local erased region, and local erasure is implemented by using a voltage difference between the corresponding conductive regions on the two conductive layers.

According to a technical solution in which local erasure is implemented by using a TFT process on a bottom base layer disclosed in the prior art, an erasing member also needs to be first positioned by using a positioning circuit to determine an erased region; and then a set voltage is applied to an upper conductive layer by using a voltage applying circuit, and on or off of a thin film transistor (TFT) of each erasing unit on the bottom base layer is controlled by using a source driver and gate driver circuit (a driver circuit) simultaneously, so that local erasure is implemented by using a voltage difference between a corresponding erasing unit on the bottom base layer and the upper conductive layer.

In the local erasure technical solution, the positioning circuit, the driver circuit, or the voltage applying circuit (which is also referred to as a row drive circuit and a column drive circuit) is an indispensable circuit structure for implementing local erasure of the liquid crystal writing board, these circuit structures increase production costs of the liquid crystal writing board to a certain extent, and a more complex circuit structure indicates a higher trouble fault rate of the liquid crystal writing board, and lower product reliability.

On the other hand, a TFT semiconductor channel forms photo-generated carriers, that is, electron-hole pairs, under light, electrons move towards a drain, and holes move toward a source, to form a hole leakage current, so that impact of the photo-generated carriers on a leakage current of a TFT device is obvious. Referring to FIG. 1, during light, due to generation of the photo-generated carriers, a conductivity of an active layer changes, that is, a photoconductive phenomenon is generated, and both on and off currents of the TFT rises compared with a case of no light, and a threshold voltage also changes correspondingly. In the prior art, when the TFT process is applied to the field of liquid crystal display, the TFT is directly exposed under irradiation of a backlight source, and the threshold voltage and an “on/off” current ratio of the TFT change due to impact of a photoconductive effect, to affect a display effect. Therefore, a liquid crystal display usually performs shading processing on the switch element TFT, to avoid impact of light on the display effect.

In the prior art, a technical solution in which a light-emitting element disposed on a writing pen, and light writing display is performed on an electrophoretic display by using a light sensitivity characteristic of the thin-film transistor TFT is disclosed. However, an objective of the technical solution is to implement writing display and improve writing delay, but cannot implement local erasure. In addition, in this solution, a light filtering layer needs to be added during processing, to allow only light of a specific wavelength (for example, red light) to pass through, resulting in an increase of the complexity and production costs of a design.

### SUMMARY

Based on this, the present invention provides a liquid crystal writing apparatus and corresponding method for implementing local erasure by using light. A base layer is divided into erasing unit arrays by using a thin film transistor (TFT) process, and local erasure of a liquid crystal writing apparatus is implemented by using a light sensitivity characteristic of a TFT; and neither a positioning circuit nor a source driver and gate driver circuit (a drive circuit) are required, to simplify a circuit structure of a product, and improve the reliability of the product.

To achieve the foregoing objective, according to a first aspect of the present invention, a liquid crystal writing apparatus for implementing local erasure by using light is provided, including: a conductive layer, a bistable liquid crystal layer, and a base layer that are sequentially arranged, where the base layer is integrated with:

a plurality of erasing units arranged in an array, where an erasing electrode and a TFT connected to the erasing electrode are disposed in each erasing unit;

at least one first conducting wire configured to supply a control voltage to the gate of each TFT; and

at least one second conducting wire configured to supply an input voltage to the source of each TFT, where

the TFT is configured to be in a critical cut off state, and then be turned on by receiving light of a set intensity, to input a set voltage to a corresponding erasing electrode, so that the erasing electrode and the conductive layer form an erasing electric field at the position, to implement local erasure; and displaying of another region that is not irradiated by the light of the set intensity is not affected.

It should be noted that, the critical cut off state of the TFT refers to that a set control voltage is applied to a gate of the TFT, a set input voltage is applied to a source of the TFT, and the TFT is in a cut off state when being not irradiated by light of a set light intensity; and when the light of the set light intensity is received, a current passing through the TFT reaches a set value, and the set voltage is applied to the erasing electrode.

When a switch element TFT is in the critical cut off state, voltages applied to a gate and a source need to be determined according to a process characteristic of the switch element TFT and a range of an applied light intensity. A person skilled in the art can perform selection according to an actual requirement through experiments, and the range of the applied light intensity may also be selected according to a design requirement.

According to a second aspect of the present invention, a light erasing apparatus is provided, applied to the liquid crystal writing apparatus for implementing local erasure by using light, where the light erasing apparatus includes:

a power supply unit, configured to supply power to other units;

a lighting unit, configured to provide a light source of a set light intensity; and

a microcontroller unit (MCU), configured to control the lighting unit to emit the light source of the set light intensity after receiving a set trigger signal.

According to a third aspect of the present invention, a local erasure method for a liquid crystal writing apparatus is provided, including:

applying a set voltage to a conductive layer, and applying set voltages to electrodes of TFTs of all or some erasing units on a base layer simultaneously, so that the TFTs are in a critical cut off state; and

providing light of a set intensity to a to-be-erased region, so that a TFT of an erasing unit corresponding to the to-be-erased region is turned on, to input a set voltage to a corresponding erasing electrode, so that the erasing electrode and the conductive layer form an erasing electric field at an irradiated position, to implement local erasure.

According to a fourth aspect of the present invention, a writing board is provided, including the liquid crystal writing apparatus for implementing local erasure by using light; or

including the liquid crystal writing apparatus for implementing local erasure by using light and the light erasing apparatus; or

implementing local erasure by using the local erasure method.

According to a fifth aspect of the present invention, a blackboard is provided, including the liquid crystal writing apparatus for implementing local erasure by using light; or

including the liquid crystal writing apparatus for implementing local erasure by using light and the light erasing apparatus; or

implementing local erasure by using the local erasure method.

According to a sixth aspect of the present invention, a drawing board is provided, including the liquid crystal writing apparatus for implementing local erasure by using light; or

including the liquid crystal writing apparatus for implementing local erasure by using light and the light erasing apparatus; or

implementing local erasure by using the local erasure method.

Compared with the prior art, the present invention has the following beneficial effects.

(1) In the present invention, a TFT process is fully used, array erasing units are integrated on a base layer, and an erased point can be reduced to be within 0.1 mm*0.1 mm, to improve control accuracy and local erasure accuracy.

(2) In the present invention, when a TFT of each erasing unit on the base layer is in a critical cut off state, the TFT can be turned on when being irradiated by light of a set light intensity; different voltages are applied to different erasing units without disposing a source driver and gate driver circuit (a driver circuit), and an erased region is positioned without disposing a positioning circuit; and a control process is simpler, production costs of a product are greatly saved, the complexity of a circuit structure is reduced, the reliability of the product is improved, and a trouble fault rate of the product is reduced.

(3) In the present invention, gates of the TFTs of the erasing units on the base layer are grouped into one group or a plurality of groups, and the same or similar voltage is applied to each group; sources of the TFTs are also grouped into one group or a plurality of groups, and the same or similar voltage is applied to each group. A voltage applying circuit is similar to a one-key erasure circuit structure, the circuit structure is simple, and the operation is convenient.

(4) In the present invention, a lighting unit of an erasing member can emit a light source when meeting a plurality of trigger conditions simultaneously, to avoid false triggering of the lighting unit to the greatest extent and reduce the damage brought to the eyes of a user as much as possible, so that a use process of the product is safe and reliable.

### BRIEF DESCRIPTION OF THE DRAWINGS

The accompanying drawings constituting a part of the present invention are used for providing further understanding for the present invention. Exemplary embodiments of the present invention and descriptions thereof are used for explaining the present invention and do not constitute any inappropriate limitation to the present invention.

FIG. 1 shows a comparison between changes of a threshold voltage and an on/off current of a TFT with light and without light;

FIG. 2 is a schematic structural diagram of a liquid crystal writing apparatus for implementing local erasure by using light according to an embodiment of the present invention;

FIG. 3 is a schematic structural diagram of a base layer of a liquid crystal writing apparatus according to an embodiment of the present invention;

FIG. 4(a) and FIG. 4(b) are schematic diagrams of connection of a TFT according to an embodiment of the present invention; and

FIG. 5 is a schematic structural diagram of an erasing member according to an embodiment of the present invention.

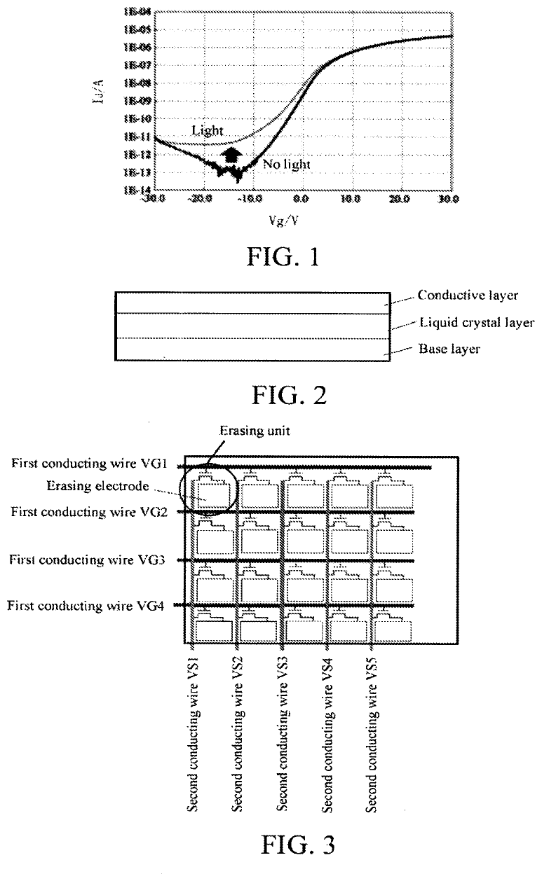

### DETAILED DESCRIPTION

It should be noted that the following detailed descriptions are all exemplary and are intended to provide further descriptions of this application. Unless otherwise specified, all technical and scientific terms used herein have the same meaning as commonly understood by a person of ordinary skill in the art to which this application belongs.

It should be noted that terms used herein are only for describing specific implementations and are not intended to limit exemplary implementations according to this application. As used herein, the singular form is intended to include the plural form, unless the context clearly indicates otherwise. In addition, it should be further understood that terms “include” and/or “comprise” used in this specification indicate that there are features, steps, operations, devices, assemblies, and/or combinations thereof.

### Embodiment 1

As described in the background art, normal display of a liquid crystal display will be affected due to impact of light on a conduction characteristic of a TFT. Therefore, in the prior art, the impact needs to be overcame by taking measures, but it cannot be conceived that a local erasure problem of a liquid crystal writing apparatus is resolved by fully using the impact.

According to the embodiments of the present invention, an embodiment of a liquid crystal writing apparatus for implementing local erasure by using light is disclosed. Referring to FIG. 2 and FIG. 3, the liquid crystal writing apparatus includes: a conductive layer, a bistable liquid crystal layer, and a base layer that are sequentially arranged from top to bottom. The conductive layer may not be divided, a plurality of erasing units are integrated on the base layer, the erasing units are arranged in an array, and an erasing electrode and a TFT connected to the erasing electrode are disposed in each erasing unit; and a voltage can be provided for the erasing electrode connected to the TFT by turning on the TFT.

The TFT can be in a critical cut off state by applying a set voltage to the TFT, and when being in the critical cut off state, the TFT can be turned on by receiving light of a set intensity.

It should be noted that, the critical cut off state of the TFT refers to that a set control voltage is applied to a gate of the TFT, a set input voltage is applied to a source of the TFT, and the TFT is in a cut off state when being not irradiated by light of a set light intensity; and when the light of the set light intensity is received, a current passing through the TFT reaches a set value, and the set voltage is applied to the erasing electrode.

The set voltage can be provided for a corresponding erasing electrode by turning on the TFT, so that the erasing electrode and the conductive layer form an electric field greater than or equal to a liquid crystal erasing electric field at the irradiated position, to cause local erasure. In addition, a TFT that is not irradiated by the light of the set intensity is still in the cut off state, and displaying of a corresponding region is not affected.

In this embodiment, the bistable liquid crystal layer is made of a bistable cholesteric liquid crystal that can implement writing through pressure. A liquid crystal state of the liquid crystal can be changed under pressure, to implement writing and displaying through the pressure; and the liquid crystal state is changed under action of a set first electric field, to implement erasure. A specific value of the first electric field is determined according to a property of the bistable cholesteric liquid crystal and a thickness of the liquid crystal.

When the TFT is in the critical cut off state, the voltages applied to the gate and the source need to be determined according to a process characteristic of the TFT and a range of an applied light intensity. A person skilled in the art can perform selection according to an actual requirement through experiments, and the range of the applied light intensity may also be selected according to a design requirement.

In this embodiment, a light source of a set light intensity (the light intensity refers to energy per unit area) may be a visible light source or may be an invisible light source such as infrared or ultraviolet. The light source may be provided by an erasing member or provided by another external light source such as a flashlight, a mobile phone lighting lamp, or an ultraviolet lamp. The external light source needs to be close to a surface of a writing board to implement local erasure. Certainly, a natural light source or an indoor normal lamp light source cannot meet a requirement of the light intensity, and local erasure cannot be implemented.

During local erasure, a set first voltage and a set second voltage are respectively applied to gates and sources of all the TFTs on the base layer, so that all the TFTs are in the critical cut off state; a set third voltage is applied to the conductive layer simultaneously; when a region on the liquid crystal writing apparatus is irradiated by light of a set intensity, a TFT of an erasing unit corresponding to the region on the base layer is turned on, to apply the second voltage to corresponding erasing electrodes; a voltage difference between the erasing electrodes and the conductive layer is |second voltage−third voltage|, and the voltage difference can reach a local erasure voltage of the liquid crystal, to implement local erasure of the region that is irradiated by the light.

Certainly, voltages may be alternatively applied to only some set TFTs according to a requirement, so that the TFTs are in the critical cut off state. In this case, local erasure can be implemented only when light is provided on a region covered by the TFTs, and because TFTs in a part outside the region are not in the critical cut off state, even if the part is irradiated by the light of the set intensity, erasure is also not implemented.

In this embodiment, the erasing voltage refers to a voltage required to completely erase handwriting, and the erasing electric field refers to an electric field formed by the erasing voltage between corresponding regions of the base layer and the conductive layer.

In this embodiment, the gates of the TFTs of the erasing units on the base layer are grouped into one group or a plurality of groups, and the same or similar voltage is applied to each group; the sources of the TFTs are also grouped into one group or a plurality of groups, and the same or similar voltage is applied to each group. A voltage applying circuit is similar to a one-key erasure circuit structure, the circuit structure is simple, and the operation is convenient.

Therefore, in a specific implementation, the gates of all the TFTs on the base layer may be connected to the same conducting wire or may be connected to different conducting wires by lead lines, and the conducting wires may be connected together in parallel for supplying power or the conducting wires may be grouped for supplying power in groups respectively. Similarly, the sources of all the TFTs on the base layer may be connected to the same conducting wire or may be connected to different conducting wires by lead lines, and the conducting wires may be connected together in parallel for supplying power or the conducting wires may be grouped for supplying power in groups respectively. Drains of all the TFTs on the base layer are respectively connected to corresponding erasing electrodes.

Referring to an example shown in FIG. 3, gates of the TFTs in each row of erasing units are connected to the same first conducting wire, sources of the TFTs in each column of erasing units are connected to the same second conducting wire, and drains of the TFTs are connected to the corresponding erasing electrodes. The same or similar voltage may be applied to each first conducting wire, and the same or similar voltage may also be applied to each second conducting wire.

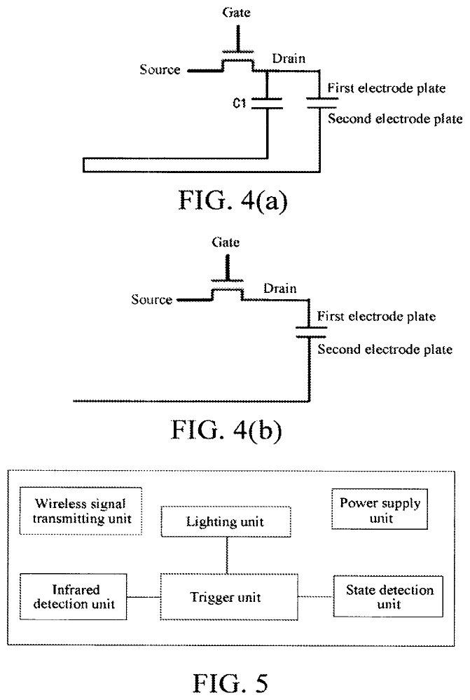

FIG. 4(a) and FIG. 4(b) are schematic diagrams of wiring of a TFT. Referring to FIG. 4(a), a first electrode plate represents a region of the erasing electrode connected to the TFT on the base layer; a second electrode plate represents the conductive layer; and the drain of the TFT may be further connected to a capacitor, a lead electrode line of each capacitor is connected to a lead electrode line of the conductive layer, and the capacitor can be charged by turning on the TFT. In FIG. 4(a), the capacitor C1 is to prevent a voltage abrupt change. Certainly, the effect of the capacitor C1 may be alternatively achieved by using a distribution capacitor formed between the conductive layer and the base layer. In this case, the capacitor C1 may be omitted, as shown in FIG. 4(b).

In this embodiment, the base layer is a TFT glass layer, and different circuit structures may be integrated on the base layer by using a semiconductor process.

In some implementations, electrode lines are respectively led out from the base layer and the conductive layer for connecting a voltage drive circuit that can provide a required voltage. Certainly, the voltage drive circuit may be alternatively integrated on the base layer.

In an optional implementation, by adding conductive particles into a sealant, electrodes of the entire conductive layer are connected to the base layer, so that electrodes of the entire module are led out from the base layer, which is simpler and more stable than an original manner in which the electrodes are respectively led out from the base layer and the conductive layer.

In this embodiment, the applied voltages that cause all or some set TFTs to be in the critical cut off state may be applied all the time, or may be applied only when local erasure is required, to reduce power consumption.

In a specific implementation, a function key may be disposed on the liquid crystal writing apparatus, and whether set voltages are applied to all or some set TFTs may be selected by using the function key, so that the TFTs are in the critical cut off state. In this manner, local erasure can be implemented by using another light source (for example, a flashlight or mobile phone lighting lamp) without a dedicated erasing apparatus.

In another specific implementation, a wireless signal receiving unit may be alternatively disposed on the liquid crystal writing apparatus, and the wireless signal receiving unit is configured to: receive a first wireless signal, to apply the set voltage to the conductive layer and apply a set voltage to a set TFT simultaneously, so that the TFT is in the critical cut off state; and

receive a second wireless signal, to cancel voltages applied to the conductive layer and the base layer.

A wireless transmission signal may be provided by a dedicated light erasing apparatus.

### Embodiment 2

According to the embodiments of the present invention, an embodiment of a light erasing apparatus is disclosed, and the light erasing apparatus may be applied to the liquid crystal writing apparatus for implementing local erasure by using light in Embodiment 1 and is configured to provide light of a set intensity to implement local erasure.

In this embodiment, the light of the set intensity is provided by the light erasing apparatus, and the light erasing apparatus includes: a power supply unit, a lighting unit, an infrared detection unit, a state detection unit, and a microcontroller unit (MCU).

The power supply unit provides a power supply to other units; and the lighting unit is configured to provide a light source of a set light intensity.

The state detection unit is configured to detect a spatial pose state of the light erasing apparatus, and send a trigger signal to the MCU when detecting that the light erasing apparatus is in a set spatial pose state.

The infrared detection unit includes an infrared transmitting end and an infrared receiving end, the infrared transmitting end and the infrared receiving end are respectively disposed on two ends of the lighting unit, and when an infrared signal sent by the infrared transmitting end is blocked by the outside, returned light is received by the infrared receiving end. If the infrared signal is blocked, it indicates that there is a blocking object in a light source irradiation direction of the lighting unit, and a trigger signal is sent to the MCU.

The MCU is configured to control the lighting unit to emit a light source when receiving a set trigger signal or meeting a set trigger condition.

In this embodiment, when the light source irradiation direction of the lighting unit is perpendicular to a blackboard surface, and there is a blocking object within a set distance in front of the lighting unit, the MCU can control the lighting unit to emit a light source. In this case, false triggering of the lighting unit can be effectively avoided, and damage caused by a strong light source to the eyes of a user can be reduced as much as possible.

Certainly, a person skilled in the art may reasonably select a trigger condition of the lighting unit according to a requirement. For example, only the infrared detection unit is used, or only the state detection unit is used.

In an optional implementation, referring to FIG. 5, a wireless signal transmitting unit is disposed on the light erasing apparatus, and the wireless signal transmitting unit is started by using a key or the wireless signal transmitting unit is started when the lighting unit on the light erasing apparatus meets the trigger condition or after the lighting unit is triggered and lighted.

The wireless signal transmitting unit transmits a wireless signal to the liquid crystal writing apparatus; and the wireless signal receiving unit on the liquid crystal writing apparatus controls application of set voltages to all or some set TFTs to cause the TFTs to be in the critical cut off state after receiving a first wireless signal, and after erasure is finished, the wireless signal receiving unit on the liquid crystal writing apparatus controls cancellation of the applied voltages after receiving a second wireless signal.

In this way, the liquid crystal writing apparatus can be controlled to apply a voltage only when erasure is required, to reduce energy consumption.

In this embodiment, a TFT is turned on by using light, so that the technical solution of local erasure of the liquid crystal writing apparatus is implemented. Compared with a commonly used film structure on the current market, the control process of local erasure is simpler and more accurate, the control circuit is simpler, the erasure effect is better, and the impact on another region is avoided; and the cost can be greatly saved, and the product reliability is ensured.

### Embodiment 3

According to the embodiments of the present invention, an embodiment of a local erasure method for a liquid crystal writing apparatus is disclosed, and the method is based on the structure of the liquid crystal writing apparatus for implementing local erasure by using light disclosed in Embodiment 1. An implementation process is as follows:

A set voltage is applied to a conductive layer, a set control voltage and a set input voltage are applied to TFTs of all or some set erasing units on a base layer, so that the TFTs are in a critical cut off state, where the control voltage is a voltage provided for a gate, and the input voltage is a voltage applied to a source.

Light of a set intensity is applied to a to-be-erased region, so that a TFT of an erasing unit of the corresponding region is turned on, to apply a set second voltage to a corresponding erasing electrode and apply a third voltage to the conductive layer, so that the second voltage and the third voltage form an erasing electric field at an irradiated position of the erasing electrode and the conductive layer, to implement local erasure.

In addition, a TFT of an erasing unit that is not irradiated by the light of the set intensity is not turned on, so that no erasing electric field is formed, and erasure cannot be implemented.

For example, the TFT is set to be in the critical cut off state when a voltage of 16V is applied to the gate and a voltage of 30V is applied to the source.

Referring to a structure of the base layer disclosed in FIG. 3, a set first voltage of 16V is respectively applied to all first conducting wires connected to gates of TFTs, a set second voltage of 30V is respectively applied to all second conducting wires connected to sources of the TFTs, and a third voltage of 0V is applied to a conductive layer; a TFT on an erasing unit corresponding to a region that is irradiated by light of a set intensity on the liquid crystal writing apparatus is turned on, and voltages of erasing electrodes corresponding to the turned-on TFTs are 30V. In this case, a voltage difference between the erasing electrodes and the conductive layer is 30V and reaches an erasing voltage of the liquid crystal writing apparatus, and local erasure of the region that is irradiated by the light can be implemented.

Certainly, the voltage values are merely exemplary, and a person skilled in the art can reasonably select each applied voltage value according to an actual requirement and a characteristic of a liquid crystal.

### Embodiment 4

Based on the liquid crystal writing apparatus for implementing local erasure disclosed in Embodiment 1 and the light erasing apparatus disclosed in Embodiment 2, or based on the local erasure method for a liquid crystal writing apparatus disclosed in Embodiment 3, a specific application product of the liquid crystal writing apparatus is disclosed. For example, the liquid crystal writing apparatus or the local erasure method in the present invention is applied to a writing board, a drawing board, or a blackboard, to achieve a local erasure function, a display function, or another disclosed function.

Specifically, the liquid crystal writing apparatus of this embodiment of the present invention may be applied to a light energy writing board, a light energy liquid crystal handwriting board, a light energy large liquid crystal writing blackboard, a light energy dust-free writing board, a light energy portable blackboard, an electronic drawing board, an LCD electronic writing board, an electronic handwriting board, an electronic note notebook, a graffiti board, a child handwriting board, a child graffiti drawing board, an eraser function sketch pad, a liquid crystal electronic drawing board, a color liquid crystal handwriting board, or another related product known to a person skilled in the art.

The specific implementations of the present invention are described above with reference to the accompanying drawings, but are not intended to limit the protection scope of the present invention. Those skilled in the art should understand that various modifications or deformations may be made without creative efforts based on the technical solutions of the present invention, and such modifications or deformations shall fall within the protection scope of the present invention.

1. A liquid crystal writing apparatus for implementing local erasure by using light, comprising: a conductive layer, a bistable liquid crystal layer, and a base layer that are sequentially arranged, wherein the base layer is integrated with:
a plurality of erasing units arranged in an array, wherein an erasing electrode and a thin film transistor (TFT) connected to the erasing electrode are disposed in each erasing unit; at least one first conducting wire configured to supply a control voltage to a gate of each TFT; and
at least one second conducting wire configured to supply an input voltage to a source of each TFT, wherein
the TFT is configured to be in a critical cut off state, and then be turned on by receiving light of a set intensity, to input a set voltage to a corresponding erasing electrode, so that the erasing electrode and the conductive layer form an erasing electric field at an irradiated position, to implement local erasure.

2. The liquid crystal writing apparatus for implementing local erasure by using light according to claim 1, wherein the critical cut off state is specifically that: a set voltage is applied to the conductive layer, and a set control voltage and a set input voltage are respectively applied to electrodes of the TFT; when receiving light of a set light intensity, the TFT is turned on; and when not receiving the light of the set light intensity, the TFT is in a cut off state.

3. The liquid crystal writing apparatus for implementing local erasure by using light according to claim 1, wherein control ends of all the TFTs are connected to the same first conducting wire;
or
control ends of all the TFTs are respectively connected to corresponding first conducting wires according to a set rule.

4. The liquid crystal writing apparatus for implementing local erasure by using light according to claim 1, wherein input ends of all the TFTs are connected to the same second conducting wire;
or
input ends of all the TFTs are respectively connected to corresponding second conducting wires according to a set rule.

5. The liquid crystal writing apparatus for implementing local erasure by using light according to claim 1, wherein the light of the set intensity comprises visible light or invisible light.

6. The liquid crystal writing apparatus for implementing local erasure by using light according to claim 1, wherein the light of the set intensity is provided by an erasing member or provided by another external light source.

7. The liquid crystal writing apparatus for implementing local erasure by using light according to claim 1, further comprising:
a wireless signal receiving unit, configured to: receive a first wireless signal, to apply the set voltage to the conductive layer and apply a set voltage to a set TFT simultaneously, so that the TFT is in the critical cut off state; and
receive a second wireless signal, to cancel voltages applied to the conductive layer and the base layer.

8. A light erasing apparatus, applied to the liquid crystal writing apparatus for implementing local erasure by using light according to claim 1, wherein the light erasing apparatus comprises:
a power supply unit, configured to supply power to other units;
a lighting unit, configured to provide a light source of a set light intensity; and
a microcontroller unit (MCU), configured to control the lighting unit to emit the light source of the set light intensity after receiving a set trigger signal.

9. A light erasing apparatus, applied to the liquid crystal writing apparatus for implementing local erasure by using light according to claim 7, wherein the light erasing apparatus comprises:
a power supply unit, configured to supply power to other units;
a lighting unit, configured to provide a light source of a set light intensity;
a microcontroller unit (MCU), configured to control the lighting unit to emit the light source of the set light intensity after receiving a set trigger signal; and
a wireless signal transmitting unit, configured to send a first wireless signal to the liquid crystal writing apparatus when erasure is required and send a second wireless signal to the liquid crystal writing apparatus after the erasure is finished.

10. The light erasing apparatus according to claim 8, further comprising: an infrared detection unit, configured to detect whether there is a blocking object in a light source irradiation direction, and send a trigger signal to the MCU when detecting that there is a blocking object.

11. The light erasing apparatus according to claim 8, further comprising:
a state detection unit, configured to detect a spatial pose state of the light erasing apparatus, and send a trigger signal to the MCU when the light erasing apparatus is in a set spatial pose state.

12. A local erasure method for a liquid crystal writing apparatus, comprising:
applying a set voltage to a conductive layer, and applying set voltages to electrodes of TFTs of all or some erasing units on a base layer simultaneously, so that the TFTs are in a critical cut off state; and
providing light of a set intensity to a to-be-erased region, so that a TFT of erasing unit corresponding to the to-be-erased region is turned on, to input a set voltage to a corresponding erasing electrode, so that the erasing electrode and the conductive layer form an erasing electric field at an irradiated position, to implement local erasure.

13. The local erasure method according to claim 12, wherein a set first voltage is applied a control voltage to gate of the TFT, and a set second voltage is applied an input voltage to source of the TFT, so that the TFT is in the critical cut off state; and a set third voltage is applied to the conductive layer, to meet|second voltage−third voltage|≥erasing voltage.

14. The local erasure method according to claim 12, wherein the same or similar voltages are respectively applied to a gate and a source of the TFT of each erasing unit, the voltage enables the TFT to be in the critical cut off state, and local erasure can be implemented when the TFT is turned on by receiving light of set intensity.

15. A writing board, comprising the liquid crystal writing apparatus for implementing local erasure by using light according to claim 1.

16. A blackboard, comprising the liquid crystal writing apparatus for implementing local erasure by using light according to claim 1.

17. A drawing board, comprising the liquid crystal writing apparatus for implementing local erasure by using light according to claim 1.

18. A writing board, comprising:
the liquid crystal writing apparatus for implementing local erasure by using light according to claim 1; and
a light erasing apparatus,
wherein the light erasing apparatus comprises:
a power supply unit, configured to supply power to other units;
a lighting unit, configured to provide a light source of a set light intensity; and
a microcontroller unit (MCU), configured to control the lighting unit to emit the light source of the set light intensity after receiving a set trigger signal.

19. A writing board implementing local erasure by using the local erasure method according to claim 12.

20. A blackboard, comprising:
the liquid crystal writing apparatus for implementing local erasure by using light according to claim 1; and
a light erasing apparatus,
wherein the light erasing apparatus comprises:
a power supply unit, configured to supply power to other units;
a lighting unit, configured to provide a light source of a set light intensity; and
a microcontroller unit (MCU), configured to control the lighting unit to emit the light source of the set light intensity after receiving a set trigger signal.
